(19) United States
(12) Patent Application Publication
(10) Pub. No.: US 2023/0059629 A1
(43) Pub. Date: Feb. 23, 2023

(54) Composite Film and Fabrication Method Therefor

(71) Applicant: JINAN JINGZHENG ELECTRONICS CO., LTD., Jinan, Shandong (CN)

(72) Inventors: Xiuquan ZHANG, Jinan, Shandong (CN); Houbin ZHU, Jinan, Shandong (CN); Zhenyu LI, Jinan, Shandong (CN); Haijiao XUE, Jinan, Shandong (CN); Yangyang LI, Jinan, Shandong (CN); Tao ZHANG, Jinan, Shandong (CN)

(21) Appl. No.: 17/793,178

(22) PCT Filed: Jan. 21, 2020
(86) PCT No.: PCT/CN2020/073534

§ 371 Date: Jul. 15, 2022

(51) Int. Cl. G02F 1/035; C23C 16/34; C23C 16/02

(52) U.S. Cl. CPC G02F 1/035; C23C 16/345; C23C 16/0227; G02F 2202/20; G02F 2202/10

(57) ABSTRACT

A composite film (100, 200) and a preparation method therefor. The composite film (100, 200) may comprise: a substrate (110, 210); a first isolation layer (130), which is located on the top surface of the substrate (110, 210); and an optical film structure (A, B), which is located on the first isolation layer (130) and comprises a stacked structure formed from a light modulation layer (150), a light transmission layer (170) and an active layer (190) that generates light. The active layer (190) may be in contact with one of the light modulation layer (150) and the light transmission layer (170).

### FIELD OF THE PRESENT DISCLOSURE

The present disclosure relates to a composite film and a fabrication method therefor, in particular to a composite film comprising an active layer, a light transmission layer and a light modulation layer and a fabrication method therefor.

### BACKGROUND OF THE PRESENT DISCLOSURE

An III-V group compound semiconductor such as indium phosphide may have a direct band gap structure and have a greater band gap (such as a band gap of greater than 1.1 eV), and a wavelength of light emitted by the III-V group compound semiconductor such as indium phosphide is suitable for optical fiber combination. Therefore, the III-V group compound semiconductor such as indium phosphide is used as a light emitting material to be widely applied to the field of optical communication.

An electrooptical material such as lithium niobate (LiNbO₃) and lithium tantalate (LiTaO₃) may have good nonlinear optical characteristics, electrooptical characteristics and acoustooptical characteristics, and it is widely applied to the field such as optical signal processing and information storage. For example, the characteristic such as the phase, amplitude, intensity or polarization state of light emitted by the above-mentioned light emitting material may be modulated based on an electrooptical effect of an electrooptical material, and then, information is loaded to an optical wave. Therefore, the above-mentioned electrooptical material may be used as a light modulation layer or waveguide layer to be widely applied to the fields such as optical communication, high-power laser synthesis, laser radar, precision measurement and sensors. However, when being used to form an optical waveguide structure, the surface of the above-mentioned electrooptical material may become very rough by using the traditional etching process as the above-mentioned electrooptical material is difficult to etch, and then, it results in the increasement of the optical loss. Therefore, in order to reduce the optical loss, a smooth etching surface is generally obtained by using a special etching technology, which restricts the application of the above-mentioned electrooptical material.

An optical waveguide material such as silicon, silicon nitride and silicon oxide has a greater forbidden bandwidth and a higher refractive index, and therefore, the optical waveguide material such as silicon, silicon nitride and silicon oxide may have a better performance of light transmission. In addition, in an existing optical waveguide preparation process, the optical waveguide material such as silicon, silicon nitride and silicon oxide is easy to process, and a preparation process of the above-mentioned optical waveguide material is completed.

In embodiments according to the present disclosure, by combination of the three above-mentioned materials, the light emitting characteristic of the III-V group compound semiconductor such as indium phosphide, the electrooptical characteristic of a material such as lithium niobate and lithium tantalate and the light transmission characteristic of the optical waveguide material such as silicon, silicon nitride and silicon oxide may be utilized at the same time, and, a composite film with excellent performances may be thus prepared. The composite film is capable of easily achieving stable and effective industrial production and has a good prospect of broad application.

### SUMMARY OF THE PRESENT DISCLOSURE

### Technical Problems

An objective of the present disclosure is to provide a composite film including a light modulation layer, a light transmission layer and an active layer.

An objective of the present disclosure is to provide a method for fabricating a composite film.

An objective of the present disclosure is to provide a composite film, to solve the problem that an electrooptical crystal such as lithium niobate is difficult to process, and accomplish the industrial production of an electrooptical device including lithium niobate and the like.

### Technical Solutions

A composite film in an embodiment according to the present disclosure may include: a substrate; a first isolation layer, which is located on a top surface of the substrate; and an optical film structure, which is located on the first isolation layer and includes a stacked structure formed from a light modulation layer, a light transmission layer and an active layer that generates light. The active layer may be in contact with one of the light modulation layer and the light transmission layer.

In an embodiment according to the present disclosure, in the optical film structure, the light modulation layer may be disposed on the first isolation layer, the light transmission layer may be disposed on the light modulation layer, and the active layer may be disposed on the light transmission layer.

In an embodiment according to the present disclosure, in the optical film structure, the active layer may be disposed on the first isolation layer, the light transmission layer may be disposed on the active layer, and the light modulation layer may be disposed on the light transmission layer.

In an embodiment according to the present disclosure, the optical film structure may further include a second isolation layer located between the light transmission layer and the light modulation layer.

In an embodiment according to the present disclosure, the composite film further includes a compensation layer located on the bottom surface, opposite to the top surface, of the substrate, wherein the compensation layer may be made of a material which is the same as that of the first isolation layer.

In an embodiment according to the present disclosure, the first isolation layer is of a monolayer structure or multi-layer structure.

In an embodiment according to the present disclosure, when the first isolation layer is of the multi-layer structure, the first isolation layer includes a stacked structure formed by alternately stacking silicon oxide and silicon nitride.

In an embodiment according to the present disclosure, the light modulation layer includes lithium niobate, lithium tantalate, KDP, DKDP or quartz.

In an embodiment according to the present disclosure, the light wave transmission layer includes silicon or silicon nitride.

In an embodiment according to the present disclosure, when being observed from a sectional view, the active layer is made from at least one of GaN, GaAs, GaSb, InP, AlAs, AlGaAs, AlGaAsP, GaAsP and InGaAsP.

A fabrication method for a composite film in an embodiment according to the present disclosure may include: depositing a first isolation layer on the upper surface of a first substrate; and forming an optical film layer on the first isolation layer. The optical film layer may include a stacked structure formed from a light modulation layer, a light transmission layer and an active layer that generates light, and the active layer is in contact with one of the light modulation layer and the light transmission layer.

In an embodiment according to the present disclosure, the step of forming an optical film layer on the first isolation layer includes: respectively forming the light modulation layer, the light transmission layer and the active layer of the optical film layer by using an ion implantation process and a wafer bonding process.

In an embodiment according to the present disclosure, the optical film layer further includes a second isolation layer located between the light modulation layer and the light transmission layer, and the second isolation layer is formed by performing a thermal oxidation process on a substrate for forming the light transmission layer.

In an embodiment according to the present disclosure, the step of forming an optical film layer on the first isolation layer may include: forming the light modulation layer on the first isolation layer, and forming the light transmission layer on the light modulation layer; and forming the active layer on the light transmission layer. The step of forming the light modulation layer may include: forming a film layer, a remainder layer and an implantation layer located between the film layer and the remainder layer in the electrooptical material substrate by implanting ions to one surface of an electrooptical material substrate by use of an ion implantation method, wherein the implanted ions are distributed in the implantation layer; forming a first bonding body by contacting the surface, with the film layer formed thereon, of the electrooptical material substrate with the upper surface of the first isolation layer; heating the first bonding body to a preset temperature and maintaining the same for a preset time, so that the film layer is transferred to the first isolation layer; and grinding and polishing the film layer to a preset thickness, such that a first composite structure including the substrate, the first isolation layer and the light modulation layer is obtained. The step of forming the light transmission layer may include: forming a film layer, a remainder layer and an implantation layer located between the film layer and the remainder layer in the light transmission material substrate by implanting ions to one surface of a light transmission material substrate by use if an ion implantation method, wherein the implanted ions are distributed in the implantation layer; forming a second bonding body by contacting the surface, with the film layer formed thereon, of the light transmission material substrate with the upper surface of the light modulation layer; heating the second bonding body to a preset temperature and maintaining the same for a preset time, so that the film layer is transferred to the light modulation layer; and grinding and polishing the film layer to a preset thickness, such that a second composite structure including the substrate, the first isolation layer, the light modulation layer and the light transmission layer is obtained. The step of forming the active layer may include: forming a film layer, a remainder layer and an implantation layer located between the film layer and the remainder layer in the active material substrate by implanting ions to one surface of an active material substrate by use of an ion implantation method, wherein the implanted ions are distributed in the implantation layer; forming a third bonding body by contacting the surface, with the film layer formed thereon, of the active material substrate with the upper surface of the light transmission layer; heating the third bonding body to a preset temperature, and maintaining the same for a preset time, so that the film layer is transferred to the light transmission layer; and grinding and polishing the film layer to a preset thickness, such that the composite film including the substrate, the first isolation layer, the light modulation layer, the light transmission layer and the active layer is obtained.

In an embodiment according to the present disclosure, the step of forming an optical film layer on the first isolation layer may include: respectively forming the light modulation layer and the active layer by using an ion implantation process and a wafer bonding process, and forming the light transmission layer by using a deposition process.

In an embodiment according to the present disclosure, the light transmission layer is formed by LPCVD.

In an embodiment according to the present disclosure, the step of forming an optical film layer on the first isolation layer may include: forming the light modulation layer on the first isolation layer; forming the light transmission layer on the light modulation layer by using the deposition process; and forming the active layer on the light transmission layer. The step of forming the light modulation layer may include: forming a film layer, a remainder layer and an implantation layer located between the film layer and the remainder layer in the electrooptical material substrate through implanting ions to one surface of an electrooptical material substrate by using an ion implantation method, wherein the implanted ions are distributed in the implantation layer;

forming a first bonding body by contacting the surface, with the film layer formed thereon, of the electrooptical material substrate with the upper surface of the first isolation layer; heating the first bonding body to a preset temperature, and maintaining the same for a preset time, so that the film layer is transferred to the first isolation layer; and grinding and polishing the film layer to a preset thickness, such that a first composite structure including the substrate, the first isolation layer and the light modulation layer is obtained. The step of forming the active layer may include: forming a film layer, a remainder layer and an implantation layer located between the film layer and the remainder layer in the active material substrate through implanting ions to one surface of an active material substrate by using an ion implantation method, wherein the implanted ions are distributed in the implantation layer; forming a fourth bonding body by contacting the surface, with the film layer formed thereon, of the active material substrate with the upper surface of the light transmission layer; heating the fourth bonding body to a preset temperature, and maintaining the same for a preset time, so that the film layer is transferred to the light transmission layer; and grinding and polishing the film layer to a preset thickness, such that the composite film including the substrate, the first isolation layer, the light modulation layer, the light transmission layer and the active layer is obtained.

In an embodiment according to the present disclosure, the step of forming an optical film layer on the first isolation layer may include: forming the light modulation layer on the first isolation layer; depositing a sacrificial isolation layer on the upper surface of a second substrate; forming the active layer on the sacrificial isolation layer; depositing the light transmission layer on the active layer by using a deposition process; forming a sixth bonding body by contacting the light transmission layer with the light modulation layer; heating the sixth bonding body to a preset temperature, and maintaining the same for a preset time; and removing the second substrate and the sacrificial isolation layer by using an etching process, to obtain the composite film. The step of forming the light modulation layer may include: forming a film layer, a remainder layer and an implantation layer located between the film layer and the remainder layer in the electrooptical material substrate through implanting ions to one surface of an electrooptical material substrate by using an ion implantation method, wherein the implanted ions are distributed in the implantation layer; forming a first bonding body by contacting the surface, with the film layer formed thereon, of the electrooptical material substrate with the upper surface of the first isolation layer; heating the first bonding body to a preset temperature, and maintaining the same for a preset time, so that the film layer is transferred to the first isolation layer; and grinding and polishing the film layer to a preset thickness, such that a first composite structure including the substrate, the first isolation layer and the light modulation layer is obtained. The step of forming the active layer may include: forming a film layer, a remainder layer and an implantation layer located between the film layer and the remainder layer in the active material substrate through implanting ions to one surface of an active material substrate by using an ion implantation method, wherein the implanted ions are distributed in the implantation layer; forming a fifth bonding body by contacting the surface, with the film layer formed thereon, of the active material substrate with the upper surface of the sacrificial isolation layer; transferring the film layer to the sacrificial isolation layer by heating the fifth bonding body to a preset temperature, and maintaining the same for a preset time; and grinding and polishing the film layer to a preset thickness, such that a third composite film including the second substrate, the sacrificial isolation layer and the active layer is obtained.

Beneficial Effects

In an embodiment according to the present disclosure, the composite film including the active layer, the light transmission layer and the light modulation layer may be obtained by using the above-mentioned method. In an embodiment according to the present disclosure, the light transmission layer made of a traditional optical waveguide material and the light modulation layer made of an electrooptical crystal such as lithium niobate can be combined to form the composite film applied to a photoelectric device, so that a complicated processing technology for lithium niobate may be avoided, and then, the industrial production of an electrooptical device including the electrooptical crystal such as lithium niobate may be accomplished. In an embodiment according to the present disclosure, the first isolation layer may be a stacked structure in which layers with different refractive indexes from each other are alternately stacked, so that a quantized potential well may be formed between the optical film structure and the substrate to reflect light leaked from the optical film structure back to the optical film structure, and then, the optical loss is reduced. In an embodiment according to the present disclosure, the compensation layer is formed on the bottom surface of the substrate, so that stresses applied to two surfaces of the substrate are counteracted with each other to diminish warpage of the substrate.

### BRIEF DESCRIPTION OF THE DRAWINGS

These and/or other aspects will be clear and easier to understand by the following descriptions for the exemplary embodiments with reference to the accompanying drawings, in which:

FIG. 1 is a sectional view of a composite film in an exemplary embodiment according to the present disclosure;

FIG. 2 is a sectional view of a photoelectric film in another exemplary embodiment according to the present disclosure; and

FIG. 3 to FIG. 15 are sectional views of a method for fabricating a composite film in an exemplary embodiment according to the present disclosure.

Reference numerals in the accompanying drawings:

| | |
|---|---|
| 100, 200-composite film | 110-first substrate |
| 130-first isolation layer | 150-light modulation layer |
| 170-light transmission layer | 190-active layer |
| 160-second isolation layer | 130′-compensation layer |
| 150-1-electrooptical material | 170-1-light transmission material |
| substrate | substrate |
| 190-1-active material substrate | 150-11, 170-11, 190-11-film layer |
| 150-12, 170-12, 190-12-separation | 150-13, 170-13, 190-13-remainder |
| layer | layer |
| 210-second substrate | 230-sacrificial isolation layer |
| A, B-optical film structure | |

### DESCRIPTION OF THE EMBODIMENTS

The principle of the present disclosure will be further described below in detail with reference to the accompanying drawings and exemplary embodiments to make the technical solutions of the present disclosure clearer. However, the present disclosure may be implemented in many different manners, but should not be explained to be limited to the embodiments described herein; on the contrary, these embodiments are provided to make the present disclosure thorough and complete, and these embodiments will sufficiently convey the concepts of the embodiments of the present disclosure to the ordinary skill in the art. When the exemplary embodiments may be implemented differently, a specific process order may be implemented in an order different from the described order. For example, two continuously described processes may be basically implemented at the same time or in an order contrary to the described order. In addition, the like reference numeral in the accompanying drawings represent the like element. In the accompanying drawings, for clarity, sizes and relative sizes of layers and regions may be exaggerated.

When an element or layer is referred to as “on (or disposed on or located on)” another element or layer or “connected to” or “coupled to” another element or layer, the element or layer may be directly on (or directly disposed on or directly located on) other element or layer or directly connected to or directly combined to other element or layer, or an intermediate element or layer is presented. However, when the element or layer is referred to as “directly on (or directly disposed on or directly located on)” other element or layer or “directly connected to” or “directly combined to” other element or layer, the intermediate element or layer is not presented.

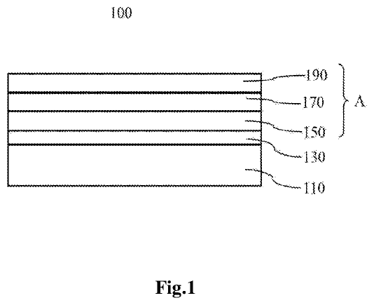

FIG. 1 is a sectional view of a composite film in an exemplary embodiment according to the present disclosure. The composite film 100 in the exemplary embodiment according to the present disclosure will be described below in detail with reference to FIG. 1.

With reference to FIG. 1, the composite film 100 in the exemplary embodiment according to the present disclosure may include a first substrate 110, a first isolation layer 130 and an optical film structure A. The optical film structure A may include a light modulation layer (or electrooptical material layer) 150, a light transmission layer 170 and an active layer 190.

Specifically, as shown in FIG. 1, the first isolation layer 130 may be disposed on the first substrate 110 and may cover the upper surface of the first substrate 110. The optical film structure A may be disposed on the first isolation layer 130 and may be separated from the first substrate 110 via the first isolation layer 130, and light leakage from the optical film structure A to the first substrate 110 may be thus avoided.

In the optical film structure A, the light modulation layer 150, the light transmission layer 170 and the active layer 190 may be stacked orderly. Specifically, the light modulation layer 150 may be disposed on the first isolation layer 130 and may be separated from the first substrate 110 via the first isolation layer 130, the light transmission layer 170 may be disposed on the light modulation layer 150 and may cover the top surface of the light modulation layer 150, and the active layer 190 may be disposed on the top surface of the light transmission layer 170. However, in an embodiment according to the present disclosure, the stacking order of the light modulation layer 150, the light transmission layer 170 and the active layer 190 is not limited thereto, for example, the active layer 190 may be in contact with one of the light modulation layer 150 and the light transmission layer 170.

Each of the layers of the composite film 100 will be described below in detail with reference to FIG. 1.

The first substrate 110 may be used for supporting a film or component located on the first substrate 110. In an exemplary embodiment according to the present disclosure, the first substrate 110 may be a silicon substrate, a quartz substrate, a silicon oxide substrate, a lithium niobate (LN, LiNbO₃) substrate or a lithium tantalate (LT, LiTaO₃) substrate and the like. However, exemplary embodiments according to the present disclosure are not limited thereto, and the first substrate 110 may be made of other appropriate materials. In an embodiment according to the present disclosure, for ease of description, the situation that the first substrate 110 is the silicon substrate is described as an example. In addition, the first substrate 110 may have the thickness ranging from a micron size to a millimeter size. For example, the thickness of the first substrate 110 may be about 0.1 mm to about 1 mm. Preferably, the thickness of the first substrate 110 may be 0.1 mm to about 0.2 mm, about 0.3 mm to about 0.5 mm or about 0.2 mm to about 0.5 mm.

The first isolation layer 130 may be located between the first substrate 110 and the optical film structure A so that the substrate 110 is separated from the optical film structure A. The first isolation layer 130 may have a refractive index smaller than that of a layer in contact with the first isolation layer 130, and then, the leakage of light transmitted in the optical film structure A may be avoided.

The first isolation layer 130 may be of a monolayer or multi-layer structure. In an exemplary embodiment according to the present disclosure, the first isolation layer 130 may be made from at least one of silicon oxide (SiOₓ) and silicon nitride (SiN_{y}), for example, the first isolation layer 130 may be of the monolayer made from SiO₂ or the multi-layer structure formed by alternately stacking SiO₂ and Si₃N₄. However, exemplary embodiments according to the present disclosure are not limited thereto, the first isolation layer 130 may be made of any appropriate materials. When the first isolation layer 130 is the multi-layer formed by alternately stacking silicon oxide (SiOₓ) and silicon nitride (SiN_{y}), there is a refractive index difference in a material layer alternately stacked in the first isolation layer 130, so that a quantized potential well may be formed between the optical film structure A and the first substrate 110, so as to further prevent light leakage and diminish the optical loss.

In addition, in an exemplary embodiment according to the present disclosure, when being observed from a sectional view, the first isolation layer 130 may have a distance ranging from about 10 nm to about 10 μm. Preferably, the thickness of the first isolation layer 130 may be about 100 nm to about 8 μm, about 500 nm to about 6 μm or about 1 μm to about 4 μm, or within any range defined by these values.

The light modulation layer 150 may be disposed on the first isolation layer 130. When being observed from a planar view, the light modulation layer 150 may cover the top surface of the first isolation layer 130. The light modulation layer 150 may be used to modulate an optical signal based on an electrooptical effect. In an exemplary embodiment according to the present disclosure, the light modulation layer 150 may include lithium niobate, lithium tantalate, KDP (Potassium Dihydrogen Phosphate), DKDP (Potassium Dideuterium Phosphate) or quartz and the like. However, embodiments according to the present disclosure are not limited thereto. In an embodiment according to the present disclosure, for ease of description, the situation that the light modulation layer 150 includes lithium niobate is described as example.

In addition, the thickness of the light modulation layer 150 may be about 100 nm to about 100 μm. Preferably, the thickness of the light modulation layer 190 may be about 200 nm to about 80 μm, about 300 nm to about 60 μm, about 400 nm to about 40 μm, about 500 nm to about 20 μm, about 600 nm to about 1 μm or within any range defined by these values, e.g., about 500 nm to about 60 μm or about 300 nm to about 40 μm and the like.

The light transmission layer 170 may be an optical waveguide layer for transmitting light. As shown in FIG. 1, the light transmission layer 170 may be disposed on the light modulation layer 150. In an exemplary embodiment according to the present disclosure, the light transmission layer 170 may be made of silicon, silicon nitride and silicon oxide. However, exemplary embodiments according to the present disclosure are not limited thereto, for example, the light transmission layer 170 may be made of any appropriate material. In an exemplary embodiment according to the present disclosure, for ease of description, the situation that the light transmission layer 170 is made of silicon or silicon nitride is described as an example.

The thickness of the light transmission layer 170 may affect the quality and capacity of light transmission. When the thickness of the light transmission layer 170 is smaller, the transmitted light may be single-mode light, with good transmission quality of the light. When the thickness of the light transmission layer 170 is increased, the mode of the transmitted light may be increased, and then, the transmission capacity is increased. However, with the thickness increment of the light transmission layer 170, the situation of frequency mixing may be caused by the increment of the mode of the transmitted light, and then, the quality of light transmission is lowered. In an embodiment according to the present disclosure, the thickness of the light transmission layer 170 may be about 50 nm to about 2 μm. Preferably, the thickness of the light transmission layer 170 may be about 50 nm to about 1.8 μm, about 50 nm to about 1.6 μm, about 200 nm to about 1.4 μm, about 400 nm to about 1.2 μm, about 600 nm to about 1 μm or within any range defined by these values, e.g., about 400 nm to about 1.8 μm or about 200 nm to about 1.6 μm and the like.

The active layer 190 may be used for generating predetermined light. As shown in FIG. 1, the active layer 190 may be disposed on the light transmission layer 170. In an exemplary embodiment according to the present disclosure, the active layer 190 may be formed from an III-V compound semiconductor. Specifically, the active layer 160 may be made of at least one of GaN, GaAs, GaSb, InP, AlAs, AlGaAs, AlGaAsP, GaAsP and InGaAsP. However, exemplary embodiments according to the present disclosure are not limited thereto. In an exemplary embodiment according to the present disclosure, for ease of description, the situation that the active layer 190 is made of InP is described as an example.

In an embodiment according to the present disclosure, the thickness of the active layer 190 may be about 50 nm to about 2 μm. Preferably, the thickness of the active layer 190 may be about 100 nm to about 1.5 μm, about 200 nm to about 1 μm, about 200 nm to about 900 nm, about 300 nm to about 700 nm, about 300 nm to about 500 nm or within any range defined by these values, e.g., about 100 nm to about 900 nm or about 200 nm to about 700 nm and the like.

Although the structure in which the light modulation layer 150, the light transmission layer 170 and the active layer 190 are stacked orderly is shown in FIG. 1, in an embodiment according to the present disclosure, the stacking order of the light modulation layer 150, the light transmission layer 170 and the active layer 190 is not limited thereto. For example, in an embodiment, the active layer 190 may be directly disposed on the first isolation layer 130, and the light modulation layer 150 may be disposed between the active layer 190 and the light transmission layer 170. In another embodiment, the active layer 190 may be directly disposed on the first isolation layer 130, and the light transmission layer 170 may be located between the active layer 190 and the light modulation layer 150.

In addition, the composite film 100 or the optical film structure A according to the present disclosure is not limited to the above-mentioned structure. For example, the composite film 100 or the optical film structure A may further include other functional layers.

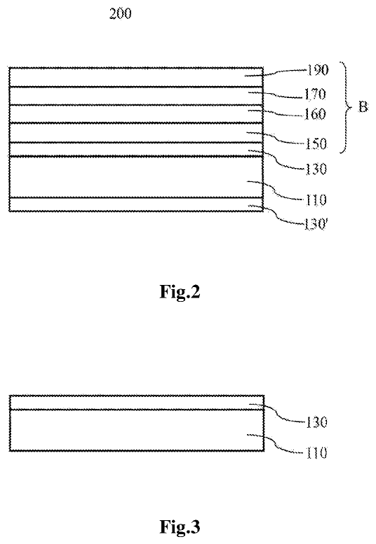

FIG. 2 is a sectional view of a photoelectric film in another exemplary embodiment according to the present disclosure. The difference of a composite film 200 or an optical film structure B as shown in FIG. 2 and the composite film 100 or the optical film structure A as shown in FIG. 1 is mainly described as below. In the text, the like reference sign in the accompanying drawings represent the same part. Moreover, in order to avoid redundancy, the repetitive description for the same element will be omitted.

As shown in FIG. 2, the composite film 200 may further include a compensation layer 130′ disposed on the bottom surface of the first substrate 110. The compensation layer 130′ may have a structure which is the same as that of the first isolation layer 130, or the compensation layer 130′ and the first isolation layer 130 may have structures symmetric with respect to the first substrate 110. Specifically, the compensation layer 130′ may be made of at least one of silicon oxide (SiOₓ) and silicon nitride (SiN_{y}), for example, the compensation layer 130′ may be of a monolayer structure made of SiO₂ or a multi-layer structure formed by alternately stacking SiO₂ and Si₃N₄. In addition, the compensation layer 130′ and the first isolation layer 130 may be formed simultaneously by using the same process. In an embodiment according to the present disclosure, the compensation layer 130′ may inhibit the warpage of the first substrate 110 when the first isolation layer 130 is formed.

As shown in FIG. 2, compared with the optical film structure A in FIG. 1, the optical film structure B may further include a second isolation layer 160 disposed between the light modulation layer 150 and the light transmission layer 170. The second isolation layer 160 may be made of silicon oxide (SiOₓ), for example, the second isolation layer 160 may be of a monolayer made of SiO₂.

The refractive index of the second isolation layer 160 may be lower than the refractive indexes of the light transmission layer 170 and the light modulation layer 150. Therefore, the second isolation layer 160 may prevent light leakage from the light transmission layer 170 to the light modulation layer 150, and then, the transmission loss of light may be reduced. In such a case, the light modulation layer 150 may be separated from the light transmission layer 170, and then, the transmission and modulation of light are independent from each other.

In an embodiment according to the present disclosure, the thickness of the second isolation layer 160 may be about 10 nm to about 100 nm. Preferably, the thickness of the second isolation layer 160 may be about 10 nm to about 90 nm, about 10 nm to about 80 nm, about 20 nm to about 70 nm, about 30 nm to about 60 nm, about 40 nm to about 50 nm or within any range defined by these values, e.g., 10 nm to about 60 nm.

FIG. 3 to FIG. 15 are sectional views of a method for fabricating a composite film in an exemplary embodiment according to the present disclosure. The method for fabricating the composite film in an exemplary embodiment according to the present disclosure will be described below in detail with reference to FIG. 3 to FIG. 15.

As shown in FIG. 3, firstly, a first substrate 110 is prepared, and then, a first isolation layer 130 is formed on the upper surface of the first substrate 110 by using a method such as a plasma enhanced chemical vapor deposition (PECVD) process, a low-pressure chemical vapor deposition (LPCVD) process or a thermal oxidation process.

For example, when the first isolation layer 130 comprises a multi-layer, silicon oxide and silicon nitride may be alternately deposited on the upper surface of the first substrate 110 by using a deposition process to form the first isolation layer 130 with a quantized potential well structure. In another embodiment according to the present disclosure, when the first isolation layer 130 comprises the monolayer, silicon oxide may be formed on the first substrate 110 by using the thermal oxidation process.

In addition, when the composite film includes a compensation layer 130′, the compensation layer 130′ may be formed on the bottom surface of the first substrate 110 while the first isolation layer 130 is formed, and the first isolation layer 130 and the compensation layer 130′ may have structures which are symmetric relative to each other.

Next, a process for forming an optical film structure on the first isolation layer 130 will be described. A light modulation layer, a light transmission layer and an active layer in the optical film structure are stacked in different orders, and therefore, the order that the light modulation layer, the light transmission layer and the active layer are formed may be changed according to the stacking order of the light modulation layer, the light transmission layer and the active layer in the optical film structure.

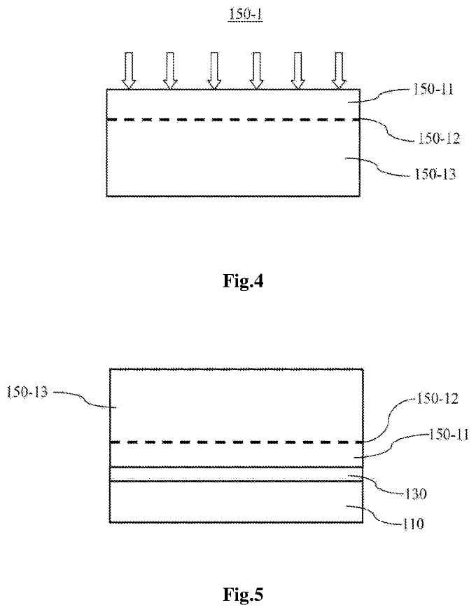

A method for respectively forming the light modulation layer, the light transmission layer and the active layer in an optical film structure A on the first isolation layer 130 by using ion implantation and wafer bonding processes will be described below with reference to FIG. 4 to FIG. 11.

FIG. 4 to FIG. 6 show a process for forming a light modulation layer 150.

As shown in FIG. 4, an electrooptical material substrate 150-1 is prepared, and then, ion implantation is performed on the electrooptical material substrate 150-1 by using an ion implantation method, so that the electrooptical material substrate 150-1 is formed with a film layer 150-11, a remainder layer 150-13 and a separation layer 150-12 located between the film layer 150-11 and the remainder layer 150-13, wherein the implanted ions are distributed in the separation layer 150-12.

When an ion implantation process is performed, ion implantation may be performed on one surface of the electrooptical material substrate 150-1 by using ions (such as H⁺, H²⁺, He⁺ or He²⁺) to form the separation layer (also known as an implantation layer) 150-12 in the electrooptical material substrate 150-1. The implanted ions may be distributed in the separation layer 150-12. The separation layer 150-12 divides the electrooptical material substrate 150-1 into two regions such as upper and lower regions: one region is a region by which most of the implanted ions pass, and is known as the film layer 150-11; and the other region is a region by which most of the implanted ions do not pass, and is known as the remainder layer 150-13. The thickness of the film layer 150-11 is decided by ion implantation energy. For example, in an exemplary embodiment according to the present disclosure, the ion implantation energy may be about 100-800 KeV, about 150-750 KeV, about 170-700 KeV, about 180-650 KeV, about 190-600 KeV, about 200-550 KeV, about 210-500 KeV, about 220-450 KeV, about 230-400 KeV, about 240-350 KeV, about 250-300 KeV or within any range defined by these values, e.g., about 160-400 KeV, about 180-600 KeV or about 200-750 KeV. In an exemplary embodiment according to the present disclosure, the ion implantation dosage may be about 1×10¹⁵-1×10¹⁷ ions/cm², about 1×10¹⁵-6×10¹⁶ ions/cm², about 1×10¹⁵-4×10¹⁶ ions/cm², about 2×10¹⁵-1×10¹⁷ ions/cm² and about 4×10¹⁵-1×10¹⁷ ions/cm² or within any range defined by these values, e.g., about 2×10¹⁵-6×10¹⁶ ions/cm² or about 2×10¹⁵-4×10¹⁶ ions/cm².

In addition, the ion implantation method may include a conventional ion implanter implantation method, a plasma immersion ion implantation method and an ion implantation method for staged implantation at different implantation temperatures.

Herein, the purpose of ion implantation is to implant a great number of ions to the surface layer of the electrooptical material substrate 150-1, the implanted ions in the separation layer 150-12 are in an unstable state in the electrooptical material substrate 150-1, the implanted ions are embedded into a lattice defect to generate volumetric strain, by which the separation layer becomes a stress concentration region, so that the mechanical strength of the part, near the separation layer 150-12, of the electrooptical material substrate 150-1 is lowered.

Next, as shown in FIG. 5, by using a wafer bonding method, the film layer 150-11 of the electrooptical material substrate 150-1 and the polished surface of the first isolation layer 130 are close to each other and then attached together, and a pressure is applied thereto to form a first bonding body as shown in FIG. 5. Due to the interaction of molecular forces (such as Van der Waals' force) on the surfaces of the film layer 150-11 and the first isolation layer 130, molecules on the two surfaces are in direct contact to form a bonding body. However, exemplary embodiments according to the present disclosure are not limited thereto. For example, the bonding body may be formed by means of an intermolecular action force instead of pressure application to two substrates. According to the present disclosure, the wafer bonding method may be selected from any one of a direct bonding method, an anode bonding method, a low-temperature bonding method, a vacuum bonding method, a plasma enhanced bonding method and an adhesive bonding method.

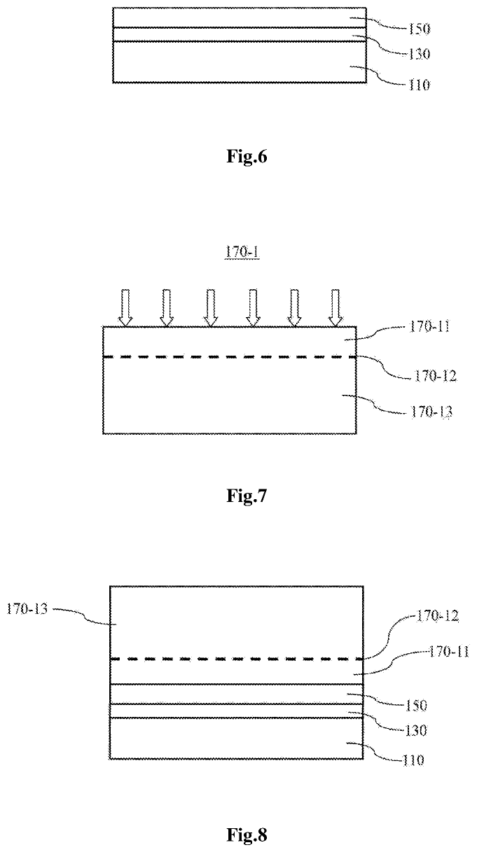

Next, as shown in FIG. 6, the first bonding body is put into a heating device and kept at a preset temperature for a preset time. In such a process, the ions in the separation layer 150-12 undergo a chemical reaction to become gas molecules or atoms and generate micro-bubbles, and with the prolonging of the heating time or the rise of the heating temperature, more and more bubbles may be generated, and the volume thereof may be gradually increased. When these bubbles are connected together as a whole, the separation of the remainder layer 150-13 from the separation layer 150-12 is achieved, so that the film layer 150-11 is transferred to the first isolation layer 130, and a first initial composite structure is formed. Next, the first initial composite structure may be put into the heating device and kept at a preset temperature for a preset time, and then, damage caused by the ion implantation process is eliminated. Then, the film layer 150-11 on the first isolation layer 130 may be ground and polished to a preset thickness, so that the light modulation layer 150 is formed on the first isolation layer 130, and a first composite structure is obtained.

FIG. 7 to FIG. 9 show a process for forming the light transmission layer 170.

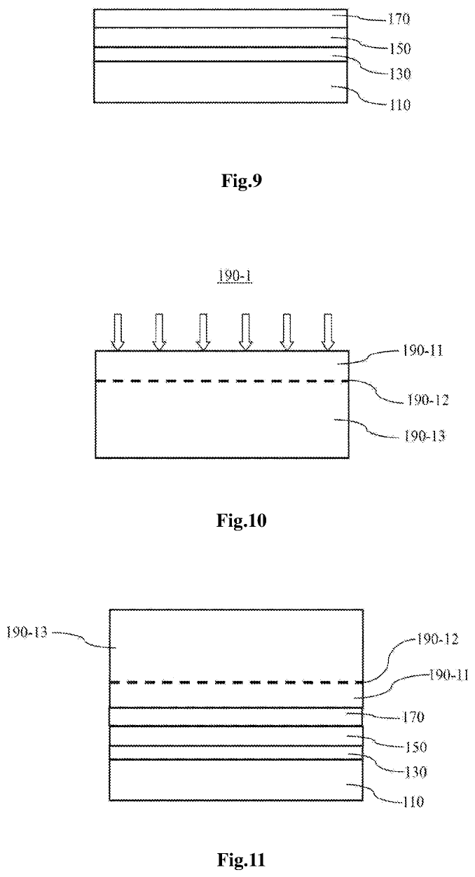

As shown in FIG. 7 and FIG. 9, similar to the process described with reference to FIG. 4 to FIG. 6, the process includes that: a light transmission material substrate 170-1 is prepared, and then, ion implantation is performed on the light transmission material substrate 170-1 by using an ion implantation method, so that the light transmission material substrate 170-1 is formed with a film layer 170-11, a remainder layer 170-13 and a separation layer 170-12 located between the film layer 170-11 and the remainder layer 170-13.

Next, by using a wafer bonding method, the film layer 170-11 of the light transmission material substrate 170-1 and the polished surface of the light modulation layer 150 of the first composite structure are closed to each other and then attached together, with a pressure applied thereto, to form a second bonding body as shown in FIG. 8.

Next, the second bonding body is put into a heating device and kept at a preset temperature for a preset time, so that the film layer 170-11 is transferred to the light modulation layer 150, and a second initial composite structure is formed. Next, the second initial composite structure may be put into the heating device and kept at a preset temperature for a preset time, and then, damage caused by the ion implantation process is eliminated. Then, the film layer 170-11 on the light modulation layer 150 may be ground and polished to a preset thickness so as to form the light transmission layer 170 on the light modulation layer 150, and a second composite structure is thus obtained.

In addition, as shown in FIG. 2, when the optical film structure B includes the second isolation layer 160 located between the light transmission layer 170 and the light modulation layer 150, a silicon oxide layer may be deposited on the light modulation layer 150 and then polished to a preset thickness to form the second isolation layer 160 before forming the light transmission layer.

However, a process for forming the light transmission layer 170 is not limited to the process described as shown in FIG. 7 to FIG. 9. For example, the light transmission layer 170 may be formed by using a deposition process. In an embodiment, when the light transmission layer 170 is made of SiNₓ, a SiNₓ layer may be deposited on the light modulation layer 150 or the active layer 190 by using the deposition process, then, a composite film is formed by using a bonding process. Thereafter, it will be described with specific embodiments.

FIG. 10 and FIG. 11 show a process for forming the active layer 190.

As shown in FIG. 10 and FIG. 11, similar to the process described with reference to FIG. 4 to FIG. 6, an active material substrate 190-1 is prepared, and then, ion implantation is performed on the active material substrate 190-1 by using an ion implantation method, so that the active material substrate 190-1 is formed with a film layer 190-11, a remainder layer 190-13 and a separation layer 190-12 located between the film layer 190-11 and the remainder layer 190-13.

Next, by using a wafer bonding method, the film layer 190-11 of the light transmission material substrate 190-1 and the polished surface of the light transmission layer 170 are closed to each other and attached together, with a pressure applied thereto, to form a third bonding body as shown in FIG. 11.

Next, the third bonding body is put into a heating device and kept at a preset temperature for a preset time, so that the film layer 190-11 is transferred to the light transmission layer 170, and a third initial composite structure is formed. Next, the third initial composite structure may be put into the heating device and kept at a preset temperature for a preset time, and then, damage caused by the ion implantation process is eliminated. Then, the film layer 190-11 on the light transmission layer 170 may be ground and polished to a preset thickness, so as to form the active layer 190 on the light transmission layer 170, and a third composite structure is thus obtained.

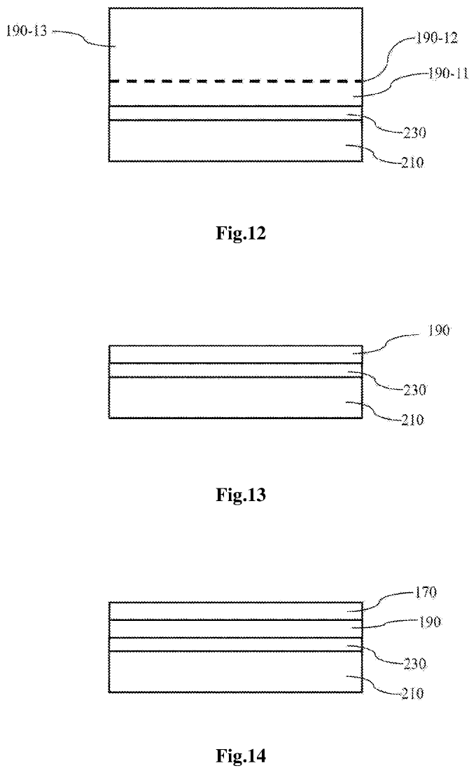

In addition, the method for fabricating the composite film in the embodiment according to the present disclosure is not limited thereto. A method for fabricating a composite film in another embodiment according to the present disclosure will be described below with reference to FIG. 12 to FIG. 15. Steps of forming the first isolation layer 130 and the light modulation layer 150 are the same as the steps described with reference to FIG. 3 to FIG. 6, the descriptions thereof will be omitted herein.

As shown in FIG. 12 and FIG. 13, a second substrate 210 is prepared, and a sacrificial isolation layer 230 is formed on the second substrate 210. Then, similar to the steps as shown in FIG. 10, ion implantation is performed on the active material substrate 190-1; and then, by using a wafer bonding method, the film layer 190-11 of the light transmission material substrate 190-1 and the polished surface of the sacrificial isolation layer 230 are closed to each other and attached together, with a pressure applied thereto, to form a fourth bonding body as shown in FIG. 12. Next, the fourth bonding body is put into a heating device and kept at a preset temperature for a preset time, so that the film layer 190-11 is transferred to the sacrificial isolation layer 230, and a fourth initial composite structure is thus formed. Next, the fourth initial composite structure may be put into the heating device and kept at a preset temperature for a preset time, and then, damage caused by the ion implantation process is eliminated. Then, the film layer 190-11 on the sacrificial isolation layer 230 may be ground and polished to a preset thickness, so as to form the active layer 190 on the sacrificial isolation layer 230, and a fourth composite structure is thus obtained.

Next, as shown in FIG. 14, the light transmission layer 170 is formed on the active layer 190 as shown in FIG. 13 by using the deposition process. However, embodiments according to the present disclosure are not limited thereto. For example, in another embodiment, the light transmission layer 170 may be formed on the light modulation layer 150 by using the deposition process.

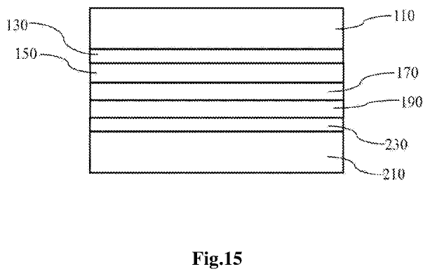

Next, as shown in FIG. 15, by using a wafer bonding method, the light transmission layer 170 and the light modulation layer 150 are closed to each other and attached together, with a pressure applied thereto, to form a fifth composite structure as shown in FIG. 15. Then, the second substrate 210 and the sacrificial isolation layer 230 are removed by dry etching to form the composite film.

The specific process of fabricating the composite film in an embodiment according to the present disclosure will be described below in detail with reference to embodiments.

### Embodiment 1

A silicon wafer substrate having the size of 3 inches and the thickness of 0.4 mm is prepared, and the silicon wafer substrate has a smooth surface. After the silicon wafer substrate is thoroughly cleaned, a SiO₂ layer having the thickness of 2 μm is formed on the smooth surface of the silicon wafer substrate by using a thermal oxidation method.

Next, a lithium niobate wafer having the size of 3 inches is prepared as an electrooptical material substrate. Helium ions (Hell with the dosage of 4×10¹⁶ ions/cm² are implanted to the lithium niobate wafer by using an ion implantation method, and the implantation energy is 200 keV. After the ions are implanted to the lithium niobate wafer, a film layer, a separation layer and a remainder layer are formed. The film layer of the lithium niobate wafer is bonded with the SiO₂ layer of the silicon wafer substrate by using a plasma bonding method to form a first bonding body. Then, the first bonding body is put into a heating device with keeping the temperature at 350° C. for 4 h until the film layer is transferred to the SiO₂ layer to obtain a first initial composite structure. The film layer is polished to 400 nm by using a chemical mechanical polishing (CMP) method to obtain a first composite structure with a lithium niobate monocrystal film having the nanoscale thickness.

Next, a silicon wafer having the size of 3 inches is prepared as a light transmission material substrate. Hydrogen ions (H⁺) with the dosage of 6×10¹⁶ ions/cm² are implanted to the silicon wafer by using an ion implantation method, and the implantation energy is 40 keV. After the ions are implanted to the silicon wafer, a film layer, a separation layer and a remainder layer are formed. The film layer of the silicon wafer is bonded with the above-mentioned lithium niobate monocrystal film by using a plasma bonding method to form a second bonding body. Then, the second bonding body is put into a heating device with keeping the temperature at 400° C. for 4 h until the film layer of the silicon wafer is transferred to the lithium niobate monocrystal film so as to obtain a second initial composite structure. Then, the second initial composite structure is put into a drying oven with keeping the temperature at 500° C. for 4 h, so that implantation damage is eliminated. Finally, a silicon monocrystal film is polished to 220 nm to obtain a second composite structure with double-layer films having the nanoscale thickness.

Next, an indium phosphide wafer having the size of 3 inches is prepared as an active material substrate. Hydrogen ions (H⁺) with the dosage of 6×10¹⁶ ions/cm² are implanted to the indium phosphide wafer by using an ion implantation method, and the implantation energy is 100 keV. After the ions are implanted to the indium phosphide wafer, a film layer, a separation layer and a remainder layer are formed. The film layer of the indium phosphide wafer is bonded with the film layer of the above-mentioned silicon wafer by using a plasma bonding method to form a third bonding body. Then, the third bonding body is put into a heating device with keeping the temperature at 400° C. for 4 h until the film layer of the indium phosphide wafer is transferred to the film layer of the above-mentioned silicon wafer so as to obtain a third initial composite structure. Then, the third initial composite structure is put into a drying oven with keeping the temperature at 500° C. for 4 h, so that implantation damage is eliminated. Finally, the film layer of the indium phosphide wafer is polished to 600 nm to obtain a composite film with three-layer films having the nanoscale thickness.

In the composite film which is obtained by using the above-mentioned method and includes an active layer, a light transmission layer and a light modulation layer, light emitted by indium phosphide serving as a self-luminescent material may be transmitted to a silicon film layer, silicon is processed to form a waveguide conveniently and is capable of transmitting light, and when the size of a silicon waveguide layer is formed to be small enough, the light may be easily transmitted to a lithium niobate layer and may be limited in a lithium niobate film layer to transversely propagate.

### Embodiment 2

A silicon wafer substrate having the size of 3 inches and the thickness of 0.4 mm is prepared, and the silicon wafer substrate has a smooth surface. After the silicon wafer substrate is thoroughly cleaned, a SiO₂ layer having the thickness of 2 μm is formed on the smooth surface of the silicon wafer substrate by using a thermal oxidation method.

Next, a lithium niobate wafer having the size of 3 inches is prepared as an electrooptical material substrate. Helium ions (Hell with the dosage of 4×10¹⁶ ions/cm² are implanted to the lithium niobate wafer by using an ion implantation method, and the implantation energy is 200 keV. After the ions are implanted to the lithium niobate wafer, a film layer, a separation layer and a remainder layer are formed. The film layer of the lithium niobate wafer is bonded with the SiO₂ layer of the silicon wafer substrate by using a plasma bonding method to form a first bonding body. Then, the first bonding body is put into a heating device with keeping the temperature at 350° C. for 4 h until the film layer is transferred to the SiO₂ layer to obtain a first initial composite structure. The film layer is polished to 400 nm by using a chemical mechanical polishing (CMP) method to obtain a first composite structure with a lithium niobate monocrystal film having the nanoscale thickness.

Next, after the first composite structure is cleaned, a Si₃N₄ film having the thickness of 700 nm is formed on the lithium niobate monocrystal film in a PECVD manner to obtain a second initial composite structure. Then, the Si₃N₄ film is polished to 200 nm to obtain a second composite structure.

Next, an indium phosphide wafer having the size of 3 inches is prepared as an active material substrate. Hydrogen ions (H⁺) with the dosage of 6×10¹⁶ ions/cm² are implanted to the indium phosphide wafer by using an ion implantation method, and the implantation energy is 100 keV. After the ions are implanted to the indium phosphide wafer, a film layer, a separation layer and a remainder layer are formed. The film layer of the indium phosphide wafer is bonded with the film layer of the above-mentioned Si₃N₄ film by using a plasma bonding method to form a second bonding body. Then, the second bonding body is put into a heating device with keeping the temperature at 400° C. for 4 h until the film layer of the indium phosphide wafer is transferred to the above-mentioned Si₃N₄ film to obtain a third initial composite structure. Then, the third initial composite structure is put into a drying oven with keeping the temperature at 500° C. for 4 h, so that implantation damage is eliminated. Finally, the film layer of the indium phosphide wafer is polished to 600 nm to obtain a composite film with three-layer films having the nanoscale thickness.

In the composite film which is obtained by using the above-mentioned method and includes an active layer, a light transmission layer and a light modulation layer, light emitted by indium phosphide serving as a self-luminescent material may be transmitted to a SiNₓ layer which is conveniently processed to form a waveguide and is capable of transmitting light, and when the size of a SiNₓ waveguide layer is made to be small enough, the light may be easily transmitted to a lithium niobate layer and may be limited in a lithium niobate film layer to transversely propagate.

By using the above-mentioned method, the composite film including the active layer, the light transmission layer and the light modulation layer can be obtained. Compared with the composite film obtained in embodiment 1, the SiNₓ layer has a refractive index close to that of the lithium niobate layer, and it is low in coupling loss and free of nonlinear absorption effect, and the transmission loss of light can be thus reduced.

### Embodiment 3

A silicon wafer substrate having the size of 3 inches and the thickness of 0.4 mm is prepared, and the silicon wafer substrate has a smooth surface. After the silicon wafer substrate is thoroughly cleaned, a SiO₂ layer having the thickness of 2 μm is formed on the smooth surface of the silicon wafer substrate by using a thermal oxidation method.

Next, a lithium niobate wafer having the size of 3 inches is prepared as an electrooptical material substrate. Helium ions (He¹⁺) with the dosage of 4×10¹⁶ ions/cm² are implanted to the lithium niobate wafer by using an ion implantation method, and the implantation energy is 200 keV. After the ions are implanted to the lithium niobate wafer, a film layer, a separation layer and a remainder layer are formed. The film layer of the lithium niobate wafer is bonded with the SiO₂ layer of the silicon wafer substrate by using a plasma bonding method to form a first bonding body. Then, the first bonding body is put into a heating device with keeping the temperature at 350° C. for 4 h until the film layer is transferred to the SiO₂ layer to obtain a first initial composite structure. The film layer is polished to 400 nm by using a chemical mechanical polishing (CMP) method to obtain a first composite structure with a lithium niobate monocrystal film having the nanoscale thickness.

Next, after a lithium niobate monocrystal film layer is cleaned, SiO₂ having the thickness of 2.5 μm is deposited on the lithium niobate monocrystal film layer by using PECVD under the condition that the temperature is 200-300° C., and then, the SiO₂ layer is ground and polished to 2 μm to form an isolation layer.

Next, a silicon wafer having the size of 3 inches is prepared as a light transmission material substrate. Hydrogen ions (H⁺) with the dosage of 6×10¹⁶ ions/cm² are implanted to the silicon wafer by using an ion implantation method, and the implantation energy is 40 keV. After the ions are implanted to the silicon wafer, a film layer, a separation layer and a remainder layer are formed. The film layer of the silicon wafer is bonded with the above-mentioned SiO₂ layer by using a plasma bonding method to form a second bonding body. Then, the second bonding body is put into a heating device with keeping the temperature at 400° C. for 4 h until the film layer of the silicon wafer is transferred to the SiO₂ layer to obtain a second initial composite structure. Then, the second initial composite structure is put into a drying oven with keeping the temperature at 500° C. for 4 h, so that implantation damage is eliminated. Finally, a silicon monocrystal film is polished to 220 nm to obtain a second composite structure with a LN/SiO₂/Si stacked structure.

Next, an indium phosphide wafer having the size of 3 inches is prepared as an active material substrate. Hydrogen ions (H⁺) with the dosage of 6×10¹⁶ ions/cm² are implanted to the indium phosphide wafer by using an ion implantation method, and the implantation energy is 100 keV. After the ions are implanted to the indium phosphide wafer, a film layer, a separation layer and a remainder layer are formed. The film layer of the indium phosphide wafer is bonded with the above-mentioned Si₃N₄ film by using a plasma bonding method to form a third bonding body. Then, the third bonding body is put into a heating device with keeping the temperature at 400° C. for 4 h until the film layer of the indium phosphide wafer is transferred to the above-mentioned silicon monocrystal film layer to obtain a third initial composite structure. Then, the third initial composite structure is put into a drying oven with keeping the temperature at 500° C. for 4 h, so that implantation damage is eliminated. Finally, the film layer of the indium phosphide wafer is polished to 600 nm to obtain a composite film with a LN/SiO₂/Si/InP stacked structure.

In the composite film which is obtained by using the above-mentioned method and includes an active layer, a light transmission layer and a light modulation layer, light emitted by indium phosphide serving as a self-luminescent material may be transmitted to a silicon layer which is conveniently processed to form a waveguide and is capable of transmitting light, and when the size of a silicon waveguide layer is formed to be small enough, the light may be easily transmitted to the SiO₂ layer, and then, the light is transmitted from the SiO₂ layer to a lithium niobate layer and may be limited in a lithium niobate film layer to transversely propagate.

By using the above-mentioned method, the composite film including the active layer, the light transmission layer and the light modulation layer can be obtained. Compared with the composite film obtained in embodiment 1, the SiO₂ layer is additionally disposed between an lithium niobate film layer and an silicon film layer, the refractive index of the SiO₂ layer is lower than the refractive indexes of the lithium niobate film layer and the silicon film layer, and therefore, light normally transmitted in the silicon film layer may be prevented from being leaked to the lithium niobate film layer, the light may be transmitted to the lithium niobate film layer only after the sectional size of the silicon film layer is reduced to a certain extent, and thus, the transmission loss of the light in the silicon film layer can be reduced.

### Embodiment 4

A silicon wafer substrate having the size of 3 inches and the thickness of 0.4 mm is prepared, and the silicon wafer substrate has a smooth surface. After the silicon wafer substrate is thoroughly cleaned, a SiO₂ layer having the thickness of 2 μm is formed on the smooth surface of the silicon wafer substrate by using a thermal oxidation method.

Next, a lithium niobate wafer having the size of 3 inches is prepared as an electrooptical material substrate. Helium ions (Hell with the dosage of 4×10¹⁶ ions/cm² are implanted to the lithium niobate wafer by using an ion implantation method, and the implantation energy is 200 keV. After the ions are implanted to the lithium niobate wafer, a film layer, a separation layer and a remainder layer are formed. The film layer of the lithium niobate wafer is bonded with the SiO₂ layer of the silicon wafer substrate by using a plasma bonding method to form a first bonding body. Then, the first bonding body is put into a heating device with keeping the temperature at 350° C. for 4 h until the film layer is transferred to the SiO₂ layer to obtain a first initial composite structure. The film layer is polished to 400 nm by using a chemical mechanical polishing (CMP) method to obtain a first composite structure with a lithium niobate monocrystal film having the nanoscale thickness.

Next, a silicon wafer substrate having the size of 3 inches and the thickness of 0.4 mm is prepared as a second substrate, and the silicon wafer substrate has a smooth surface. After the silicon wafer substrate is thoroughly cleaned, a SiO₂ layer having the thickness of 2 μm is formed on the smooth surface of the silicon wafer substrate by using a thermal oxidation method.

Next, an indium phosphide wafer having the size of 3 inches is prepared as an active material substrate. Hydrogen ions (H⁺) with the dosage of 6×10¹⁶ ions/cm² are implanted to the indium phosphide wafer by using an ion implantation method, and the implantation energy is 100 keV. After the ions are implanted to the indium phosphide wafer, a film layer, a separation layer and a remainder layer are formed. The film layer of the indium phosphide wafer is bonded with the above-mentioned SiO₂ layer on the silicon wafer serving as the second substrate by using a plasma bonding method to form a second bonding body. Then, the second bonding body is put into a heating device with keeping the temperature at 400° C. for 4 h until the film layer of the indium phosphide wafer is transferred to the above-mentioned SiO₂ layer on the silicon wafer serving as the second substrate to obtain a second initial composite structure. Then, the second initial composite structure is put into a drying oven with keeping the temperature at 500° C. for 4 h, so that implantation damage is eliminated. Finally, the film layer of the indium phosphide wafer is polished to 600 nm to obtain a second composite structure.

Next, after the second composite structure is cleaned, a Si₃N₄ film having the thickness of 200 nm is formed on an indium phosphide monocrystal film by using LPCVD.

Next, the lithium niobate film layer of the cleaned first composite structure is bonded with the Si₃N₄ film on the second composite structure by using a plasma bonding method to obtain a third bonding body. Then, the third bonding body is put into a drying oven with keeping the temperature at 350° C. for 4 h. Next, the silicon substrate and the SiO₂ layer of the second composite structure are removed by dry etching to prepare the composite film.

Compared with the method described in embodiment 2, the H content of the SiNₓ layer prepared by using the LPCVD is lower than that of the SiNₓ layer prepared by using the PECVD, and then, the transmission loss of light can be reduced.

### Embodiment 5

A silicon wafer substrate having the size of 3 inches and the thickness of 0.4 mm is prepared, and the silicon wafer substrate has a smooth surface. After the silicon wafer substrate is thoroughly cleaned, a SiO₂ layer having the thickness of 2 μm is formed on the smooth surface of the silicon wafer substrate by using a thermal oxidation method.

Next, a lithium niobate wafer having the size of 3 inches is prepared as an electrooptical material substrate. Helium ions (Hell with the dosage of 4×10¹⁶ ions/cm² are implanted to the lithium niobate wafer by using an ion implantation method, and the implantation energy is 200 keV. After the ions are implanted to the lithium niobate wafer, a film layer, a separation layer and a remainder layer are formed. The film layer of the lithium niobate wafer is bonded with the SiO₂ layer of the silicon wafer substrate by using a plasma bonding method to form a first bonding body. Then, the first bonding body is put into a heating device with keeping the temperature at 350° C. for 4 h until the film layer is transferred to the SiO₂ layer to obtain a first initial composite structure. The film layer is polished to 400 nm by using a chemical mechanical polishing (CMP) method to obtain a first composite structure with a lithium niobate monocrystal film having the nanoscale thickness.

Next, a silicon wafer having the size of 3 inches and the thickness of 0.4 mm is prepared as a light transmission material substrate. After the silicon wafer substrate is thoroughly cleaned, a SiO₂ layer having the thickness of 2 μm is formed on the smooth surface of the silicon wafer substrate by using a thermal oxidation method. Next, hydrogen ions (H⁺) with the dosage of 6×10¹⁶ ions/cm² are implanted to the silicon wafer by using an ion implantation method, and the implantation energy is 100 keV. After the ions are implanted to the silicon wafer, a film layer, a separation layer and a remainder layer are formed. The SiO₂ layer on the film layer of the silicon wafer is bonded with the above-mentioned lithium niobate monocrystal film layer by using a plasma bonding method to form a second bonding body. Then, the second bonding body is put into a heating device with keeping the temperature at 400° C. for 4 h until the film layer of the silicon wafer is transferred to the lithium niobate monocrystal film layer to obtain a second initial composite structure. Then, the second initial composite structure is put into a drying oven with keeping the temperature at 500° C. for 4 h, so that implantation damage is eliminated. Finally, a silicon monocrystal film is polished to 220 nm to obtain a second composite structure with a LN/SiO₂/Si stacked structure.

Next, an indium phosphide wafer having the size of 3 inches is prepared as an active material substrate. Hydrogen ions (H⁺) with the dosage of 6×10¹⁶ ions/cm² are implanted to the indium phosphide wafer by using an ion implantation method, and the implantation energy is 100 keV. After the ions are implanted to the indium phosphide wafer, a film layer, a separation layer and a remainder layer are formed. The film layer of the indium phosphide wafer is bonded with the above-mentioned silicon monocrystal film by using a plasma bonding method to form a third bonding body. Then, the third bonding body is put into a heating device with keeping the temperature at 400° C. for 4 h until the film layer of the indium phosphide wafer is transferred to the above-mentioned silicon monocrystal film layer to obtain a third initial composite structure. Then, the third initial composite structure is put into a drying oven with keeping the temperature at 500° C. for 4 h, so that implantation damage is eliminated. Finally, the film layer of the indium phosphide wafer is polished to 600 nm to obtain a composite film with a LN/SiO₂/Si/InP stacked structure.

Compared with the composite film obtained in embodiment 3, as the second isolation layer is prepared by using the thermal oxidation method, the H content of the SiO₂ layer prepared by thermal oxidation is lower than that of the SiO₂ layer prepared by using the PECVD, and, the transmission loss of light can be thus reduced.

After the above-mentioned composite film is obtained, corresponding photoelectric devices may be formed by using an etching process, a deposition process, a photoetching process and the like. An example in which a photoelectric device is prepared by using the above-mentioned composite film in an embodiment according to the present disclosure will be described below with reference to embodiment 6.

### Embodiment 6

A silicon wafer substrate having the size of 3 inches and the thickness of 0.4 mm is prepared, and the silicon wafer substrate has a smooth surface. After the silicon wafer substrate is thoroughly cleaned, a SiO₂ layer having the thickness of 2 μm is formed on the smooth surface of the silicon wafer substrate by using a thermal oxidation method.

Next, an indium phosphide wafer having the size of 3 inches is prepared as an active material substrate. Hydrogen ions (H⁺) with the dosage of 6×10¹⁶ ions/cm² are implanted to the indium phosphide wafer by using an ion implantation method, and the implantation energy is 100 keV. After the ions are implanted to the indium phosphide wafer, a film layer, a separation layer and a remainder layer are formed. The film layer of the indium phosphide wafer is bonded with the SiO₂ layer of the above-mentioned silicon substrate by using a plasma bonding method to form a first bonding body. Then, the first bonding body is put into a heating device with keeping the temperature at 400° C. for 4 h until the film layer of the indium phosphide wafer is transferred to the above-mentioned SiO₂ layer to obtain a first initial composite structure. Then, an indium phosphide monocrystal film layer is polished to 600 nm to obtain a first composite structure with an indium phosphide monocrystal film having the nanoscale thickness.

Next, a lithium niobate wafer having the size of 3 inches is prepared as an electrooptical material substrate. Helium ions (He¹⁺) with the dosage of 4×10¹⁶ ions/cm² are implanted to the lithium niobate wafer by using an ion implantation method, and the implantation energy is 200 keV. After the ions are implanted to the lithium niobate wafer, a film layer, a separation layer and a remainder layer are formed. The film layer of the lithium niobate wafer is bonded with the indium phosphide monocrystal film layer by using a plasma bonding method to form a second bonding body. Then, the second bonding body is put into a heating device with keeping the temperature at 350° C. for 4 h until the film layer is transferred to the indium phosphide monocrystal film layer to obtain a second initial composite structure. A lithium niobate film layer is polished to 400 nm by using a chemical mechanical polishing (CMP) method to obtain a second composite structure with an indium phosphide (InP)/lithium niobate (LN) stacked structure.

Next, a silicon wafer having the size of 3 inches and the thickness of 0.4 mm is prepared as a light transmission material substrate. After the silicon wafer substrate is thoroughly cleaned, a SiO₂ layer having the thickness of 2 μm is formed on the smooth surface of the silicon wafer substrate by using a thermal oxidation method. Next, hydrogen ions (H⁺) with the dosage of 6×10¹⁶ ions/cm² are implanted to the silicon wafer by using an ion implantation method, and the implantation energy is 100 keV. After the ions are implanted to the silicon wafer, a film layer, a separation layer and a remainder layer are formed. The SiO₂ layer on the film layer of the silicon wafer is bonded with the above-mentioned lithium niobate monocrystal film layer by using a plasma bonding method to form a third bonding body. Then, the third bonding body is put into a heating device with keeping the temperature at 400° C. for 4 h until the film layer of the silicon wafer is transferred to the lithium niobate monocrystal film layer to obtain a third initial composite structure. Then, the third initial composite structure is put into a drying oven with keeping the temperature at 500° C. for 4 h, so that implantation damage is eliminated. Finally, a silicon monocrystal film is polished to 220 nm to obtain a third composite structure with an InP/LN/SiO₂/Si stacked structure.

Next, an optical film layer in the above-mentioned structure is etched by using an ICP process, so that the above-mentioned optical film layer is formed with a preset pattern. Then, an electrode is prepared on the preset pattern of the optical film layer by using processes such as deposition and photoetching etc., and then, a M-Z modulation device is obtained.

In an embodiment according to the present disclosure, the composite film including the active layer, the light transmission layer and the light modulation layer may be obtained by using the above-mentioned method. In an embodiment according to the present disclosure, the light transmission layer formed by a traditional optical waveguide material and the light modulation layer form by an electrooptical crystal such as lithium niobate are combined to form the composite film applied to a photoelectric device, so that a complicated processing technology for lithium niobate may be avoided, and then, the industrial production of an electrooptical device including the electrooptical crystal such as lithium niobate may be achieved. In an embodiment according to the present disclosure, the first isolation layer may be a stacked structure in which layers with respectively different refractive indexes are alternately stacked, so that a quantized potential well may be formed between the optical film structure and the substrate to reflect light leaked from the optical film structure back thereto, and the optical loss is thus reduced. In an embodiment according to the present disclosure, the compensation layer is formed on the bottom surface of the substrate, so that stresses applied to two surfaces of the substrate counteract with each other to improve warpage of the substrate.

Although an optical waveguide integrated device in an exemplary embodiment according to the present disclosure is described as above with reference to the accompanying drawings, the present disclosure is not limited thereto. It is understood by the skill in the art that various variations of its formalities and details may be made without departing from the spirit and scope of the present disclosure.

What is claimed is:

1. A composite film, wherein the composite film comprises:
a substrate;
a first isolation layer, which is located on a top surface of the substrate; and
an optical film structure, which is located on the first isolation layer and comprises a stacked structure formed by a light modulation layer, a light transmission layer and an active layer that generates light,
wherein the active layer is in contact with one of the light modulation layer and the light transmission layer.

2. The composite film of claim 1, wherein in the optical film structure, the light modulation layer is disposed on the first isolation layer, the light transmission layer is disposed on the light modulation layer, and the active layer is disposed on the light transmission layer.

3. The composite film of claim 1, wherein in the optical film structure, the active layer is disposed on the first isolation layer, the light transmission layer is disposed on the active layer, and the light modulation layer is disposed on the light transmission layer.

4. The composite film of claim 1, wherein the optical film structure further comprises a second isolation layer located between the light transmission layer and the light modulation layer.

5. The composite film of claim 1, wherein the composite film further comprises a compensation layer located on the bottom surface, opposite to the top surface, of the substrate,
wherein the compensation layer has the same material as that of the first isolation layer.

6. The composite film of claim 1, wherein the first isolation layer is of a monolayer structure or multi-layer structure.

7. The composite film of claim 6, wherein when the first isolation layer is of the multi-layer structure, the first isolation layer comprises a stacked structure formed by alternately stacking silicon oxide and silicon nitride.

8. The composite film of claim 1, wherein the light modulation layer comprises lithium niobate, lithium tantalate, KDP, DKDP or quartz.

9. The composite film of claim 1, wherein the light wave transmission layer comprises silicon or silicon nitride.

10. The composite film of claim 1, wherein the active layer is formed by at least one of GaN, GaAs, GaSb, InP, AlAs, AlGaAs, AlGaAsP, GaAsP and InGaAsP.

11. A method for fabricating a composite film, wherein the method comprises:
depositing a first isolation layer on an upper surface of a first substrate; and
forming an optical film layer on a first isolation layer,
wherein the optical film layer comprises a stacked structure formed by a light modulation layer, a light transmission layer and an active layer that generates light, and the active layer is in contact with one of the light modulation layer and the light transmission layer.

12. The method of claim 11, wherein the step of forming the optical film layer on the first isolation layer comprises: respectively forming the light modulation layer, the light transmission layer and the active layer of the optical film layer by using an ion implantation process and a wafer bonding process.

13. The method of claim 12, wherein the optical film layer further comprises a second isolation layer located between the light modulation layer and the light transmission layer, and the second isolation layer is formed by performing a thermal oxidation process on a substrate for forming the light transmission layer.

14. The method of claim 11, wherein the step of forming the optical film layer on the first isolation layer comprises: respectively forming the light modulation layer and the active layer by using an ion implantation process and a wafer bonding process, and forming the light transmission layer by using a deposition process.

15. The method of claim 14, wherein the light transmission layer is formed by LPCVD.
